(19) United States
(12) Patent Application Publication
(10) Pub. No.: US 2025/0283597 A1
(43) Pub. Date: Sep. 11, 2025

(54) CONTROL DEVICE, FOREIGN SUBSTANCE REMOVAL DEVICE, AND CONTROL METHOD

(71) Applicant: FUJI CORPORATION, Chiryu (JP)

(72) Inventor: Hironori KONDO, Nagoya-shi (JP)

(73) Assignee: FUJI CORPORATION, Chiryu (JP)

(21) Appl. No.: 18/706,829

(22) PCT Filed: Dec. 14, 2021
(86) PCT No.: PCT/JP2021/045928

§ 371 Date: May 2, 2024

(51) Int. Cl. F23G 5/02

(52) U.S. Cl. CPC F23G 5/02; F23G 2201/602

(57) ABSTRACT

A control device of the present disclosure is used in a foreign substance removal device including a removal section configured to pick up and remove a foreign substance from a waste material conveyed by a conveyance device, a dust-proof section configured to perform dust-proofing related to maintenance of the foreign substance removal device with respect to powder dust derived from the waste material, and an imaging section located upstream of the removal section and configured to capture an image of the waste material. The control device executes one or more of control processing of controlling the dust-proof section based on information regarding an amount of waste material obtained from an image captured by the imaging section, and output processing of outputting information regarding the maintenance of the foreign substance removal device based on the information regarding the amount of waste material obtained from the image captured by the imaging section.

### TECHNICAL FIELD

The present description discloses a control device, a foreign substance removal device, and a control method.

### BACKGROUND ART

Conventionally, a processing device containing combustible powder dust has been proposed in which a combustible material such as waste plastic as a waste material is crushed by a crusher and burned in a heat process furnace (for example, refer to Patent Literature 1). In this processing device, the height of a processed object is detected using a height sensor, and the supply amount of the water vapor is controlled according to the height, so that the occurrence of powder dust explosion can be prevented in advance.

### PATENT LITERATURE

Patent Literature 1: JP-A-2007-46797

### SUMMARY OF THE INVENTION

### Technical Problem

However, Patent Literature 1 does not consider maintenance of the device. For example, it is desirable that appropriate maintenance can be executed when removing a foreign substance from the waste material.

The present disclosure has been made to solve such a problem, and a main object thereof is to provide a control device, a foreign substance removal device, and a control method capable of executing more appropriate maintenance when removing a foreign substance from a waste material.

The present disclosure employs the following means in order to achieve the main object described above.

A control device disclosed in the present description is a control device used in a foreign substance removal device including a removal section configured to pick up and remove a foreign substance from a waste material conveyed by a conveyance device, a dust-proof section configured to perform dust-proofing related to maintenance of the foreign substance removal device with respect to powder dust derived from the waste material, and an imaging section located upstream of the removal section and configured to capture an image of the waste material, the control device including
a control section configured to execute one or more of control processing of controlling the dust-proof section based on information regarding an amount of waste material obtained from the captured image captured by the imaging section, and output processing of outputting information regarding the maintenance of the foreign substance removal device based on the information regarding the amount of waste material obtained from the captured image captured by the imaging section.

In this control device, the control processing of controlling the dust-proof section that performs dust-proofing related to the maintenance of the foreign substance removal device is executed based on the information regarding the amount of waste material obtained from the captured image obtained by capturing the image of the waste material. Alternatively, the control device executes the output processing of outputting the information regarding the maintenance of the foreign substance removal device based on the information regarding the amount of waste material obtained from the captured image obtained by capturing the image of the waste material. In this control device, since the information on control and maintenance of the dust-proof section is output according to an increase or decrease in the amount of waste material, it is possible to execute more appropriate maintenance of the device when removing the foreign substance from the waste material.

### BRIEF DESCRIPTION OF DRAWINGS

FIG. 1 is a diagram illustrating an example of a configuration of recycling system 10.

FIG. 2 is a view illustrating an example of a schematic configuration of foreign substance removal device 30.

FIG. 3 is a perspective view illustrating an example of a schematic configuration of removal section 34.

FIG. 4 is a diagram illustrating an example of information stored in storage section 52.

FIG. 5 is a graph of correspondence relationship information 55 including a correspondence relationship between a waste material image and the amount of powder dust.

FIG. 6 is a graph of correspondence relationship information 55 including a correspondence relationship between the amount of powder dust and the dust-proof control amount.

FIG. 7 is a diagram illustrating an example of captured images 81 and 82 of recognition section 31.

FIG. 8 is a flowchart illustrating an example of a foreign substance removal processing routine.

FIG. 9 is a flowchart illustrating an example of a dust-proof control output processing routine.

FIG. 10 is a graph of correspondence relationship information including a correspondence relationship between a waste material image and the amount of waste materials.

FIG. 11 is a graph of correspondence relationship information including a correspondence relationship between the amount of waste materials and the dust-proof control amount.

FIG. 12 is a flowchart illustrating an example of another dust-proof control output processing routine.

### DESCRIPTION OF EMBODIMENTS

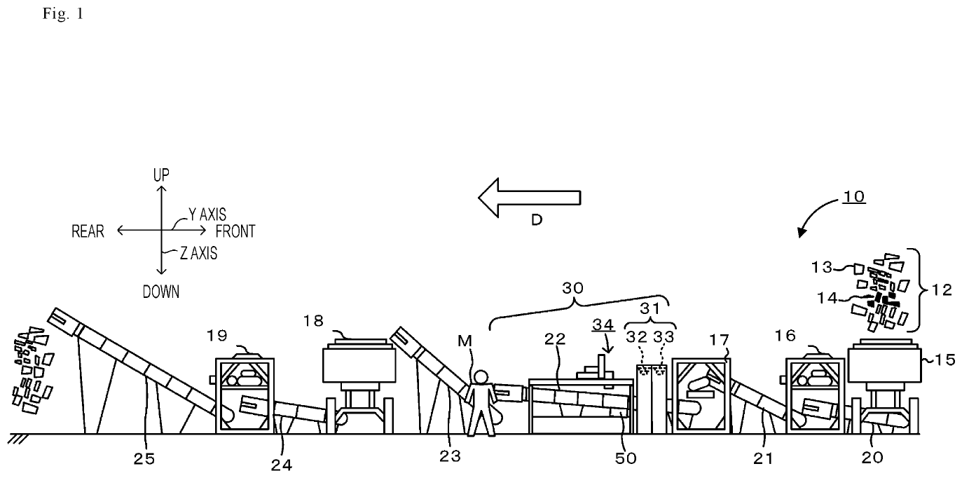

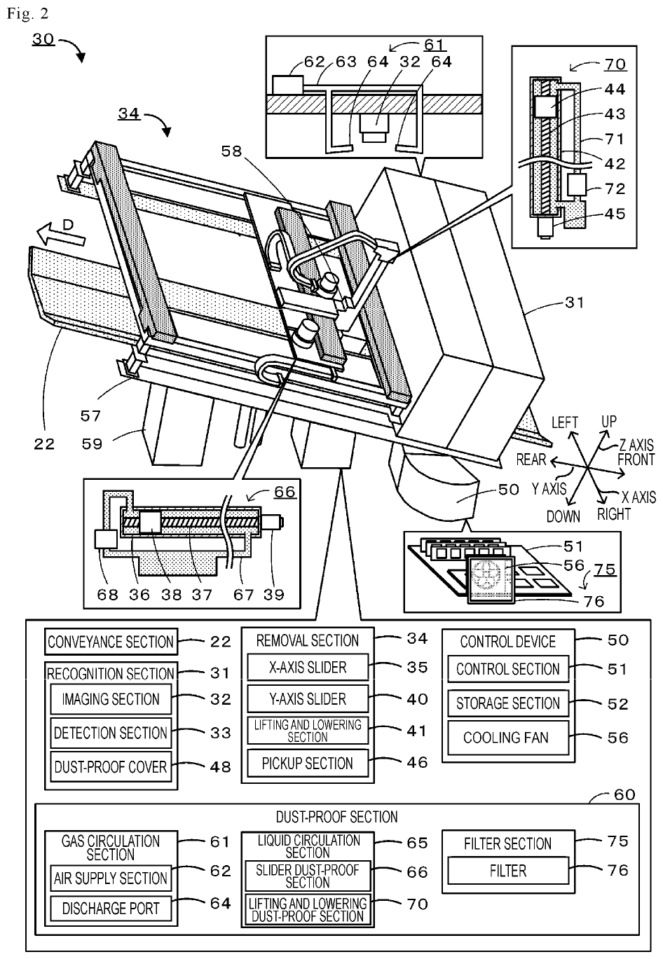

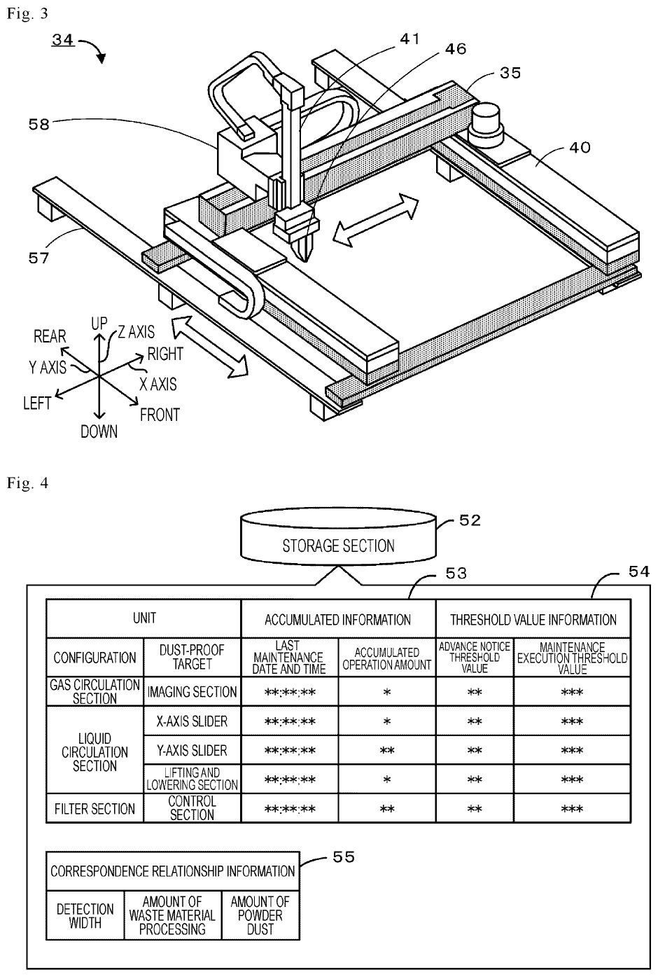

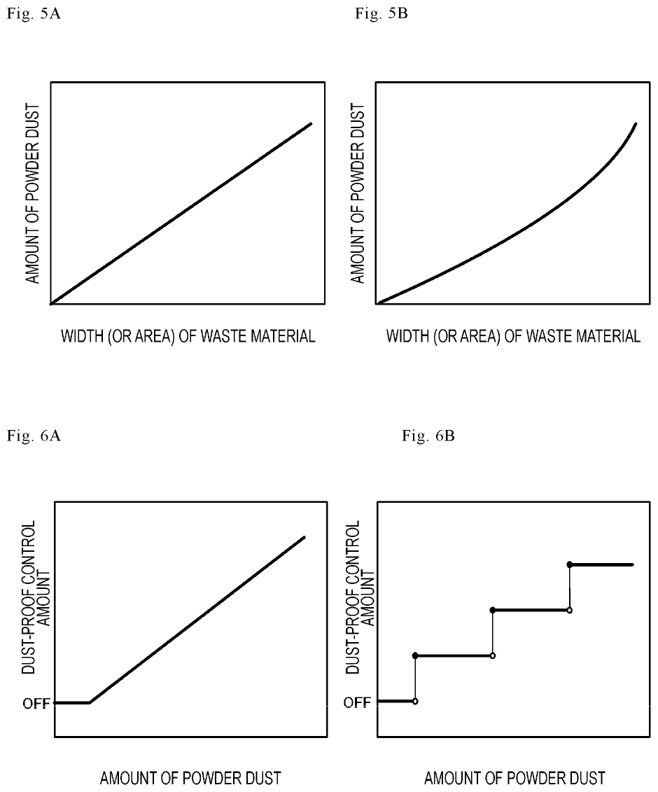

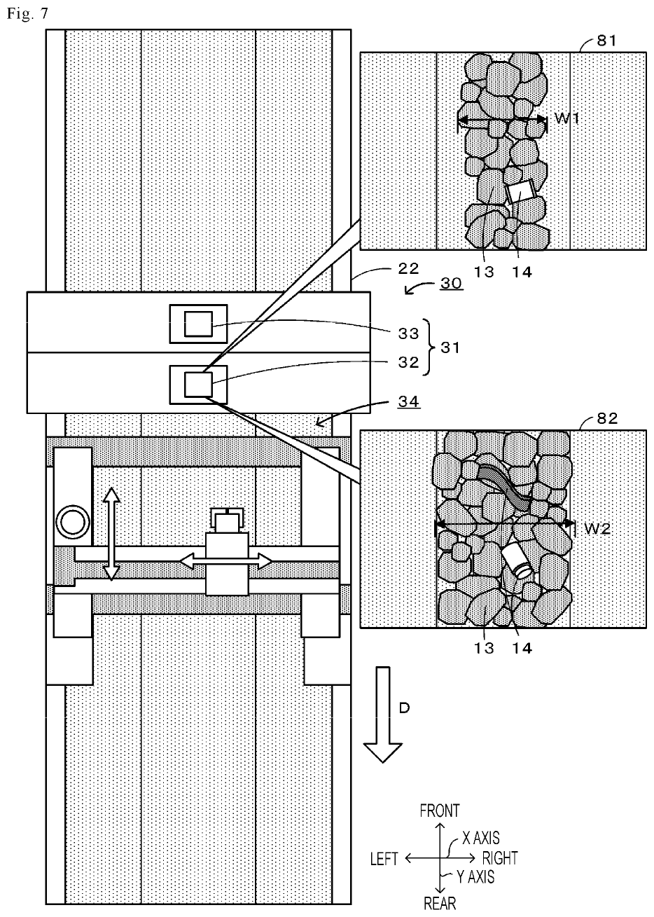

An embodiment of the present disclosure will be described with reference to the accompanying drawings. FIG. 1 is a diagram illustrating an example of a configuration of recycling system 10 for recycling waste material. FIG. 2 is a view illustrating an example of a schematic configuration of foreign substance removal device 30. FIG. 3 is a perspective view illustrating an example of a schematic configuration of removal section 34. FIG. 4 is a diagram illustrating an example of accumulated information 53, threshold value information 54, and correspondence relationship information 55 stored in storage section 52. FIG. 5 is a diagram illustrating an example of correspondence relationship information 55 including a correspondence relationship between a waste material image and the amount of powder dust in a captured image. FIG. 6 is a diagram illustrating an example of correspondence relationship information 55 including the correspondence relationship between the amount of powder dust and the dust-proof control amount. FIG. 7 is a diagram illustrating an example of captured images 81 and 82 of recognition section 31. In the present embodiment, a left-right direction, a front-rear direction, and an up-down direction are as illustrated in FIGS. 1 to 3, and 7. In addition, in the present embodiment, a direction where waste material 12 is conveyed is referred to as conveyance direction D.

Waste material 12 processed by recycling system 10 is a mixture obtained by mixing target object 13, which is a target for recycling such as stone, sand, and concrete, with foreign substance 14 including paper, resin, wood, metal, or the like. As illustrated in FIG. 1, recycling system 10 includes primary crusher 15, primary magnetic separator 16, screen machine 17, foreign substance removal device 30, secondary crusher 18, secondary magnetic separator 19, and conveyance devices 20 to 25.

Primary crusher 15 is a device that primarily crushes waste material 12 as a raw material. Primary crusher 15 crushes waste material 12 so as to have a predetermined primary size or less (for example, 40 cm or less), for example. Primary magnetic separator 16 is a device that removes the foreign substance of magnetic material contained in waste material 12 by magnetic force. Screen machine 17 is, for example, a device that separates waste material 12 having a primary size or more and waste material 12 having a size less than the primary size by passing waste material 12 over a mesh. Secondary crusher 18 is a device that secondarily crushes waste material 12 to a size smaller than that of primary crusher 15. Secondary crusher 18 crushes waste material 12 so as to have a predetermined secondary size or less (for example, 10 cm or less). Secondary magnetic separator 19 is a device that removes, from waste material 12, the magnetic material not removed by primary magnetic separator 16 and foreign substance removal device 30.

Conveyance devices 20 to 25 as conveyance lines are devices that place waste material 12 on a conveyance surface and convey waste material 12 along conveyance direction D, and are configured as, for example, belt conveyors. Conveyance devices 20 to 25 may have configurations other than the belt conveyor as long as waste material 12 is conveyed.

Foreign substance removal device 30 is a device that is placed on the conveyance surface of conveyance device 22, conveys waste material 12 in the conveyance line, and removes foreign substance 14. As illustrated in FIG. 2, foreign substance removal device 30 includes recognition section 31, removal section 34, control device 50, and dust-proof section 60. Conveyance device 22 places waste material 12 on the conveyance surface and conveys waste material 12 at a predetermined conveyance speed.

Recognition section 31 is disposed upstream of removal section 34 in conveyance direction D. Recognition section 31 includes imaging section 32 that captures an image of foreign substance 14 contained in waste material 12 conveyed by conveyance section 22, and detection section 33 that detects the height of waste material 12. Imaging section 32 is configured as, for example, a camera that captures an image of waste material 12 placed on conveyance surface 30 of conveyance device 22 and conveyed. Imaging section 32 is held above the conveyance surface of conveyance device 22 by a holding member provided so as to straddle conveyance device 22 in the left-right direction. Imaging section 32 captures an image of a predetermined range including waste material 12 from above the conveyance surface of conveyance device 22, and outputs image data to control device 50 of foreign substance removal device 30. As illustrated in FIG. 7, imaging section 32 captures captured images 81 and 82 including target object 13 and foreign substance 14. Control device 50 acquires widths W1 and W2 of waste material 12 from the captured image, and acquires the amount of waste materials 12, the amount of powder dust from waste material 12, and the like. Detection section 33 detects the height of waste material 12 on conveyance device 22. For example, detection section 33 may be provided upstream of removal section 34 in conveyance direction D, and may be configured as a stereo camera including two cameras. Detection section 33 is held above conveyance surface of conveyance device 22 by the holding member provided so as to straddle conveyance device 22 in the left-right direction. Detection section 33 outputs information regarding the detected height of waste material 12 to control device 50. As illustrated in FIG. 2, recognition section 31 may include dust-proof cover 48 that covers imaging section 32. Foreign substance removal device 30 including detection section 33 can perform conveyance control of waste material 12 using information in the height direction of waste material 12. Foreign substance removal device 30 may omit detection section 33 or may omit the use of information on the height of waste material 12.

Removal section 34 is a device that removes foreign substance 14 from waste material 12 conveyed by conveyance device 22, and is configured as, for example, an XY robot. Removal section 34 removes foreign substance 14 present in waste material 12 based on the captured image captured by imaging section 32. Removal section 34 is provided downstream of recognition section 31 in conveyance direction D. Removal section 34 includes X-axis slider 35, Y-axis slider 40, lifting and lowering section 41 (refer to FIG. 5), pickup section 46, support portion 57, removal head 58, and dust box 59. Removal section 34 discards pickup foreign substance 14 into dust box 59 disposed on the side of conveyance device 22. Removal section 34 may have another configuration such as an articulated arm robot.

X-axis slider 35 includes a guide rail installed along a direction orthogonal to conveyance direction D of conveyance device 22, a slider that moves along the guide rail, and drive mechanism 36 that drives the slider. The guide rail is fixed to a slider of Y-axis slider 40 installed on conveyance section 22 along conveyance direction D. Removal head 58 provided with lifting and lowering section 41 is fixed to the slider. Drive mechanism 36 may be, for example, a linear motion mechanism using a ball screw including screw shaft 37, nut 38, and motor 39. Drive mechanism 36 is not particularly limited as long as it is a linear motion mechanism, and may be a linear motor or the like. In X-axis slider 35, removal head 58 is moved along the X-axis direction by drive mechanism 36.

Y-axis slider 40 includes a guide rail installed along conveyance direction D, a slider that moves along the guide rail, and a drive mechanism that drives the slider. The guide rail is fixed to support portion 57 installed on conveyance section 22 along conveyance direction D. X-axis slider 35 is disposed on the slider. The drive mechanism may be, for example, a linear motion mechanism using a ball screw including a screw shaft, a nut, and a motor. The drive mechanism has the same configuration as that of drive mechanism 36, and the description thereof is omitted. In Y-axis slider 40, X-axis slider 35 is moved along the Y-axis direction by the drive mechanism.

Lifting and lowering section 41 is fixed to removal head 58 disposed on X-axis slider 35. Lifting and lowering section 41 includes drive mechanism 42 that lifts and lowers pickup section 46 along the Z-axis. Drive mechanism 42 may be, for example, a linear motion mechanism using a ball screw including screw shaft 43, nut 44, and motor 45. Drive mechanism 42 is not particularly limited as long as it is a linear motion mechanism, and may be a linear motor or the like. In lifting and lowering section 41, pickup section 46 is lifted and lowered along the Z-axis direction by drive mechanism 42.

Pickup section 46 includes multiple gripping claws. Pickup section 46 grips and releases foreign substance 14 by the opening and closing operation of the gripping claws, and picks up and removes foreign substance 14 from waste material 12. Pickup section 46 is opened and closed by a grip drive section (not illustrated). Pickup section 46 is moved in the X, Y, and Z directions within a predetermined range of conveyance section 22 by X-axis slider 35, Y-axis slider 40, and lifting and lowering section 41.

Dust-proof section 60 is a unit that performs dust-proofing related to maintenance of foreign substance removal device 30 on powder dust derived from waste material 12. Here, the term “dust-proofing” includes, for example, preventing powder dust from entering the inside of the device and removing the powder dust outside the device in a case where the powder dust enters the inside of the device. Dust-proof section 60 includes, for example, gas circulation section 61 for circulating gas for removing powder dust from waste material 12, liquid circulation section 65 for circulating liquid for removing powder dust from waste material 12, and filter section 75 for filtering powder dust from waste material 12. Gas circulation section 61 performs dust-proofing by circulating gas in recognition section 31, for example. Examples of the gas include air. Specifically, for example, gas circulation section 61 may blow a gas onto the lens surface of imaging section 32 to suppress the adhesion of powder dust. In this case, gas circulation section 61 includes air supply section 62, supply pipe 63, and discharge port 64. Air supply section 62 may be a compressor that discharges compressed air. Supply pipe 63 is a tubular member that circulates gas from gas circulation section 61 to imaging section 32. Discharge port 64 is an opening portion opened toward the lens surface of imaging section 32. In gas circulation section 61, cleaning of air supply section 62, supply pipe 63, and the like is executed depending on usage conditions including the amount of powder dust and the like, as maintenance. Alternatively, for example, gas circulation section 61 may prevent powder dust from entering dust-proof cover 48 by circulating gas in dust-proof cover 48 of recognition section 31. In this case, in gas circulation section 61, the adjustment of the flow rate of the gas to be circulated is executed depending on usage conditions including the amount of powder dust and the like, as maintenance.

Liquid circulation section 65 is, for example, a device that washes away powder dust entering a movable section such as X-axis slider 35, Y-axis slider 40, and lifting and lowering section 41 with liquid. Examples of the liquid include oil. Liquid circulation section 65 includes slider dust-proof section 66 disposed on X-axis slider 35 and Y-axis slider 40, and lifting and lowering dust-proof section 70 disposed on lifting and lowering section 41. Slider dust-proof section 66 includes cleaning liquid tube 67 and circulation pump 68. Cleaning liquid tube 67 is a tubular member through which a liquid circulates, and is connected to both end portions of drive mechanism 36. Circulation pump 68 is a liquid feed pump, and circulates the liquid into drive mechanism 36 via cleaning liquid tube 67. Lifting and lowering dust-proof section 70 includes cleaning liquid tube 71 and circulation pump 72. Cleaning liquid tube 71 is a tubular member through which a liquid circulates, and is connected to both end portions of drive mechanism 42. Circulation pump 72 is a liquid feed pump, and circulates the liquid into drive mechanism 42 via cleaning liquid tube 71. A filter (not illustrated) is disposed inside liquid circulation section 65. The filter separates foreign substances such as powder dust. In liquid circulation section 65, cleaning, filter exchange, and the like of cleaning liquid tubes 67 and 71, circulation pumps 68 and 72, and the like are executed depending on usage conditions including the amount of powder dust and the like, as maintenance. In filter section 75, filter 76 is detachably disposed outside cooling fan 56 of control device 50. Filter section 75 does not include a drive section that is controlled according to the amount of powder dust, but filter 76 is exchanged depending on usage conditions including the amount of powder dust and the like, as maintenance.

Control device 50 is a device that controls entire foreign substance removal device 30, and includes control section 51, storage section 52, and cooling fan 56. Control section 51 is configured as a microprocessor centered on the CPU, and controls the entire device. Control section 51 outputs control signals to recognition section 31, removal section 34, and dust-proof section 60, and inputs signals from recognition section 31, removal section 34, and dust-proof section 60. Control section 51 executes one or more of the control processing of controlling dust-proof section 60 based on information regarding the amount of waste materials 12 obtained from the captured image captured by imaging section 32 and the output processing of outputting information regarding the maintenance of each configuration of foreign substance removal device 30 based on the information regarding the amount of waste materials 12 obtained from the captured image captured by imaging section 32. For example, control section 51 acquires the amount of powder dust from waste material 12 as the information regarding the amount of waste materials 12 from the captured image captured by imaging section 32. Control section 51 may acquire the amount of waste materials as the information regarding the amount of waste materials 12. Storage section 52 is a storage medium for storing information and includes, for example, an HDD or a flash memory. Cooling fan 56 performs waste heat for operating control section 51, and is driven to a stepwise air blowing amount according to a load of control section 51.

As illustrated in FIG. 4, storage section 52 stores various control programs in addition to accumulated information 53, threshold value information 54, correspondence relationship information 55, and the like. Accumulated information 53 is information in which the last maintenance execution date and time and the accumulated operation amount accumulated from the maintenance execution date and time are associated with each configuration of dust-proof section 60. Examples of the configuration of dust-proof section 60 include gas circulation section 61 for performing dust-proofing for imaging section 32, liquid circulation section 65 for performing dust-proofing for X-axis slider 35, Y-axis slider 40, and lifting and lowering section 41, and filter section 75 for performing dust-proofing for control device 50. The accumulated operation amount indicates a value obtained by accumulating the operation amount in which the load is added according to the amount of powder dust from waste material 12. Threshold value information 54 is information in which an advance notice threshold value and a maintenance execution threshold value are associated with each configuration of dust-proof section 60. The advance notice threshold value indicates entering a preparation period for maintenance execution based on the accumulated operation amount. The maintenance execution threshold value indicates entering the period for actually executing maintenance.

Correspondence relationship information 55 is information used when the amount of powder dust is acquired from the information on the waste material included in the captured image captured by imaging section 32 and the control amount of dust-proof section 60 is acquired from the amount of powder dust. Correspondence relationship information 55 can obtain the amount of powder dust from waste material 12 by using at least width W substantially orthogonal to conveyance direction D of waste material 12 included in the captured image. Correspondence relationship information 55 includes a correspondence relationship in which width W of waste material 12 in the captured image illustrated in FIG. 5 is associated with the amount of powder dust, and a correspondence relationship in which the amount of powder dust illustrated in FIG. 6 is associated with the control amount of dust-proof section 60. Correspondence relationship information 55 has, for example, a correspondence relationship in which the larger width W of waste material 12 obtained from the captured image or the area of waste material 12 obtained from width W, the larger the amount of powder dust is obtained. In addition, in correspondence relationship information 55, the control amount for controlling dust-proof section 60 is associated with a tendency that the smaller the amount of powder dust from waste material 12 obtained from the captured image, the more the operation of dust-proof section 60 is suppressed. In addition, in correspondence relationship information 55, the control amount for controlling dust-proof section 60 is associated with a tendency that the larger the amount of powder dust from waste material 12 obtained from the captured image, the more the operation of dust-proof section 60 is increased. The term “with a tendency” refers to the correspondence relationship as a whole, but it means that it is caused to include a part of a portion of the correspondence relationship that is different from the correspondence relationship, such as a constant value or an inverse correspondence relationship. The correspondence relationship related to each configuration may be empirically obtained by experiments or the like. The correspondence relationship for obtaining the amount of powder dust may be a linear relationship as illustrated in FIG. 5A or a curved relationship as illustrated in FIG. 5B. In addition, the correspondence relationship for obtaining the control amount may be a proportional relationship as illustrated in FIG. 6A with respect to a configuration in which the stepless control is possible, or may be a stepwise relationship as illustrated in FIG. 6B with respect to a configuration in which only the stepwise control is possible.

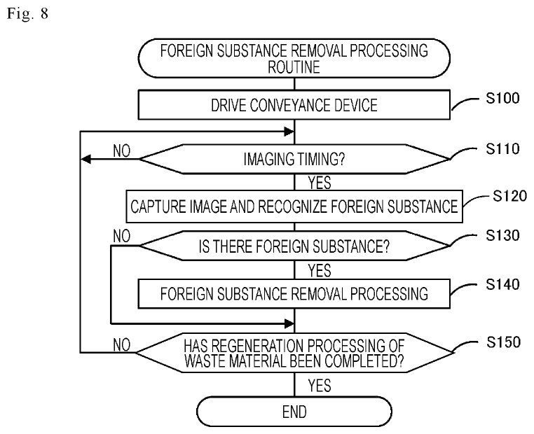

Next, the operation of foreign substance removal device 30 configured as described above will be described. First, the processing of removing foreign substance 14 from waste material 12 will be described. FIG. 8 is a flowchart illustrating an example of a foreign substance removal processing routine executed by control section 51 of control device 50. This routine is stored in storage section 52, and is executed by control section 51 after foreign substance removal device 30 is activated. When this routine is started, control section 51 drives conveyance device 22 (S100), and determines whether it is an imaging timing (S110). The imaging timing may be set to a timing at which entire waste material 12 conveyed by conveyance device 22 is captured as a seamless still image. In a case where imaging section 32 images a moving image, this processing needs only to be omitted. When it is not the imaging timing in S110, control section 51 stands by as it is. When it is the imaging timing in S110, control section 51 causes imaging section 32 to capture the captured image and acquire the captured image to perform recognition processing of foreign substance 14 (S120). For example, control section 51 performs the processing of detecting a region different from the luminance of target object 13 and setting the region as the region of foreign substance 14, as recognition processing of foreign substance 14. Next, control section 51 determines whether there is foreign substance 14 (S130), and when there is foreign substance 14, executes foreign substance removal processing (S140). In the foreign substance removal processing, control section 51 moves pickup section 46 to the region where foreign substance 14 is recognized, grips foreign substance 14, and then executes processing of moving foreign substance 14 to dust box 59. After S140 or when there is no foreign substance 14 in S130, control section 51 determines whether the regeneration processing of waste material 12 is completed (S150). When the regeneration processing is not completed, control section 51 repeatedly executes the processing at S110 and the subsequent steps. Conversely, when the regeneration processing is completed in S150, control section 51 ends this routine. As described above, in foreign substance removal device 30, the removal processing of foreign substance 14 is executed using the captured image obtained by imaging waste material 12 on conveyance device 22.

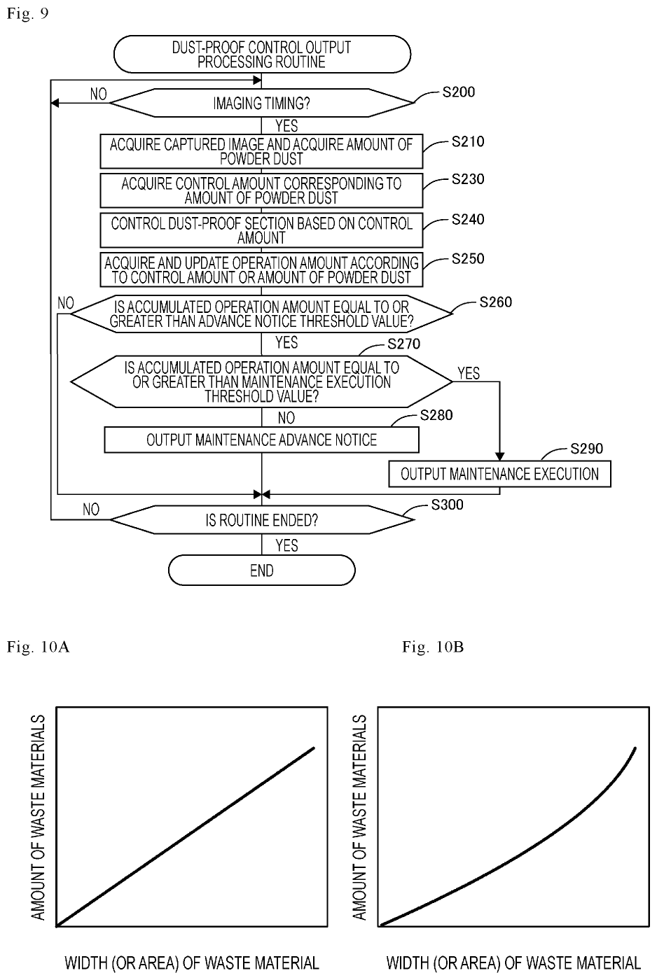

Next, processing in which foreign substance removal device 30 notifies the execution of dust-proofing for each configuration and the maintenance of each configuration will be described. FIG. 9 is a flowchart illustrating an example of a dust-proof control output processing routine executed by control section 51. This routine is stored in storage section 52, and is executed by control section 51 in parallel with the foreign substance removal processing. Here, a case where the amount of powder dust derived from waste material 12 is acquired as the information regarding the amount of waste materials 12 and used for the processing will be mainly described. When this routine is started, control section 51 determines whether it is an imaging timing (S200) as in S110. When it is not the imaging timing, control section 51 stands by as it is. When it is the imaging timing, control section 51 acquires the captured image captured by imaging section 32, and acquires the amount of powder dust from waste material 12 as the information regarding the amount of waste materials based on correspondence relationship information 55 (S210). Control section 51 acquires width W of waste material 12 on conveyance device 22 from the captured image at predetermined intervals along conveyance direction D. Control section 51 acquires the information regarding the amount of waste materials by using the information including at least width W of waste material 12. Control section 51 may obtain the amount of powder dust from width W of waste material 12. Alternatively, control section 51 may obtain the area of waste material 12 using width W and the predetermined intervals to obtain the amount of powder dust corresponding thereto. As illustrated in FIG. 7, width W of waste material 12 is correlated with the amount of waste materials 12 present on conveyance device 22. Control section 51 can obtain the amount of waste materials and the amount of powder dust according to width W using correspondence relationship information 55 empirically obtained as illustrated in FIGS. 5 and 6.

Next, control section 51 acquires the control amount of dust-proof section 60 corresponding to the acquired amount of powder dust using correspondence relationship information 55 (S230). Examples of the control amount include the amount of air supplied by air supply section 62, the amount of liquid fed by circulation pump 68, the amount of liquid fed by circulation pump 72, and the like. Since control section 51 sets the control amount based on correspondence relationship information 55, control section 51 sets the control amount of dust-proof section 60 with a tendency that the smaller the amount of powder dust from waste material 12 obtained from the captured image, the more the operation of dust-proof section 60 is suppressed. In addition, since control section 51 sets the control amount based on correspondence relationship information 55, control section 51 sets the control amount of dust-proof section 60 with a tendency that the larger the amount of powder dust from waste material 12 obtained from the captured image, the more largely dust-proof section 60 is operated. Next, control section 51 drives and controls dust-proof section 60 using the set control amount (S240). Control section 51 acquires the operation amount corresponding to the control amount or the amount of powder dust, and updates accumulated information 53 with the acquired operation amount (S250). For example, control section 51 updates the accumulated operation amounts according to the control amounts thereof for air supply section 62 and circulation pumps 68 and 72 that are directly driven. In addition, control section 51 updates the accumulated operation amount according to the amount of powder dust for filter section 75 which is not directly driven. For example, when the standard operation amount is 1, control section 51 may accumulate the operation amount according to the ratio to the standard control amount or the amount of powder dust. For example, when the accumulated operation amount is set to 10 in a case where the operation amount 1 continues for 10 minutes, control section 51 sets the accumulated operation amount to 5 in a case where the operation amount 0.5 continues for 10 minutes. In addition, in a case where the operation amount of 1.5 continues for 10 minutes, control section 51 sets the accumulated operation amount to 15. In dust-proof section 60, when a load of the dust-proof processing is smaller, the accumulated operation amount also becomes a smaller value, and when a load of the dust-proof processing is larger, the accumulated operation amount also becomes a larger value.

When the accumulated operation amount of dust-proof section 60 is updated in S250, control section 51 determines whether the accumulated operation amount is equal to or greater than the advance notice threshold value set in threshold value information 54 (S260). Control section 51 executes the determination of the advance notice threshold value for each of the configurations of dust-proof section 60. When the accumulated operation amount is equal to or greater than the advance notice threshold value, control section 51 determines whether the accumulated operation amount is equal to or greater than the maintenance execution threshold value (S270). When the accumulated operation amount is equal to or greater than the advance notice threshold value and less than the maintenance execution threshold value, control section 51 outputs a maintenance advance notice to the configuration of dust-proof section 60 (S280). For example, the maintenance advance notice may be one that displays and outputs information to the effect that maintenance is executed soon on a display section such as an operation panel. Worker M who has confirmed this notice can prepare to execute maintenance for the configuration of dust-proof section 60. Conversely, when the accumulated operation amount is equal to or greater than the advance notice threshold value and is equal to or greater than the maintenance execution threshold value, control section 51 outputs the maintenance execution to the configuration of dust-proof section 60 (S290). Here, control section 51 may be a section that displays and outputs information to the effect that maintenance is executed on a display section such as an operation panel. In addition, control section 51 may output information on the exchange of filter 76 as the information regarding the maintenance. In a case where the maintenance is not executed and the device is left, control section 51 may stop the operation of foreign substance removal device 30 after a predetermined period has elapsed in order to prevent a failure of the device. Since the accumulated operation amount of dust-proof section 60 corresponds to the amount of powder dust from waste material 12, control section 51 notifies the worker of the information regarding the maintenance in a longer period when the amount of powder dust from waste material 12 is small. Conversely, when the amount of powder dust from waste material 12 is large, control section 51 notifies the worker of the information regarding the maintenance in a shorter period.

After S290, after S280, or when the accumulated operation amount is less than the advance notice threshold value in S260, control section 51 determines whether to end the dust-proof control output routine (S300). For example, in a case where the regeneration processing of waste material 12 is completed, control section 51 determines to end the dust-proof control output routine. Alternatively, upon receiving an instruction to end the dust-proof control output routine, control section 51 determines to end the dust-proof control output routine. For example, the instruction to end the dust-proof control output routine may be input by the worker via the operation panel. When it is determined that the dust-proof control output routine is not ended, control section 51 executes the processing at S200 and the subsequent steps. Conversely, when it is determined to end the dust-proof control output routine, control section 51 ends this routine. As described above, in foreign substance removal device 30, the information regarding the amount of waste materials 12 is obtained using the captured image obtained by capturing the image of waste material 12 on conveyance device 22, the control amount of dust-proof section 60 is changed according to the information, the operation amount according to the control amount or the amount of powder dust is accumulated, and the maintenance is executed at a more appropriate timing.

Here, a correspondence relationship between the elements of the present embodiment and the elements of the present disclosure will be clarified. Foreign substance removal device 30 of the present embodiment is an example of the foreign substance removal device of the present disclosure, control device 50 is an example of the control device, imaging section 32 is an example of the imaging section, removal section 34 is an example of the removal section, dust-proof section 60 is an example of the dust-proof section, and control section 51 is an example of the control section. In addition, conveyance device 22 is an example of the conveyance device, waste material 12 is an example of the waste material, and foreign substance 14 is an example of the foreign substance. In the present embodiment, an example of the control method for the present disclosure is also clarified by describing the operation of foreign substance removal device 30.

Foreign substance removal device 30 described above includes removal section 34 that picks up and removes foreign substance 14 from waste material 12 conveyed by conveyance device 22, dust-proof section 60 that performs dust-proofing related to the maintenance of foreign substance removal device 30 with respect to powder dust derived from waste material 12, and imaging section 32 located upstream of removal section 34 and that captures the image of waste material 12. In addition, control device 50 includes control section 51 that executes one or more of control processing of controlling dust-proof section 60 based on the information regarding the amount of waste materials 12 obtained from the captured image captured by imaging section 32 and output processing of outputting the information regarding the maintenance of foreign substance removal device 30 based on the information regarding the amount of waste materials 12 obtained from the captured image captured by imaging section 32. Control device 50 executes the control processing of controlling dust-proof section 60 that performs dust-proofing related to the maintenance of foreign substance removal device 30 based on the amount of powder dust as the information regarding the amount of waste materials 12 obtained from the captured image obtained by capturing the image of waste material 12. Alternatively, control device 50 executes the output processing of outputting the information regarding the maintenance of foreign substance removal device 30 based on the amount of powder dust as the information regarding the amount of waste materials 12 obtained from the captured image obtained by capturing the image of waste material 12. In control device 50, since the information on the control and the maintenance of dust-proof section 60 is output according to the increase and decrease in the amount of waste materials 12, it is possible to execute more appropriate maintenance of the device when removing foreign substance 14 from waste material 12.

In addition, control section 51 acquires the amount of powder dust as the information regarding the amount of waste materials from the captured image, and executes the control processing and/or the output processing based on the acquired amount of powder dust. In control device 50, since the amount of powder dust derived from waste material 12 can be obtained from the captured image, it is possible to more appropriately execute the maintenance of the device based on the amount of powder dust. Furthermore, control section 51 executes one or more of the control processing of controlling dust-proof section 60 based on the amount of powder dust and the output processing of outputting the information regarding the maintenance of foreign substance removal device 30 based on the amount of powder dust. In control device 50, the control processing and the output processing can be more appropriately executed using the amount of powder dust obtained from the captured image. Furthermore, control section 51 obtains the amount of waste materials 12 and/or the amount of powder dust from waste material 12 based on information including at least width W of the waste material included in the captured image. In control device 50, the information regarding the amount of waste materials can be obtained by relatively easy processing using information including at least the width of waste material 12. In addition, control section 51 may obtain the amount of waste materials and/or the amount of powder dust from the waste material from width W of the waste material included in the captured image, or may obtain the area by using width W of the waste material included in the captured image, and obtain the amount of waste materials and/or the amount of powder dust from the waste material from the area. In addition, control section 51 may obtain the information regarding the amount of waste materials by using correspondence relationship information 55 that empirically associates the information including at least width W of waste material 12 with the amount of waste materials and/or the amount of powder dust.

In addition, control section 51 executes the control processing of controlling dust-proof section 60 with a tendency that the smaller the amount of waste materials 12 obtained from the captured image and/or the amount of powder dust from waste material 12 obtained from the captured image, the more the operation of dust-proof section 60 is suppressed. In control device 50, it is possible to further suppress an excessive operation of dust-proof section 60 or the like according to the amount of waste materials 12, and it is possible to more appropriately execute maintenance of the device. Furthermore, control section 51 executes the output processing of outputting the information regarding the maintenance with a tendency that the smaller the amount of waste materials 12 obtained from the captured image and/or the amount of powder dust from waste material 12 obtained from the captured image, the longer an output interval of the information regarding the maintenance of foreign substance removal device 30. In control device 50, it is possible to further suppress the execution of excessive maintenance of dust-proof section 60 or the like according to the amount of waste materials 12, and it is possible to more appropriately execute maintenance of the device. Furthermore, control section 51 executes the control processing of controlling dust-proof section 60 with a tendency that the larger the amount of waste materials 12 obtained from the captured image and/or the amount of powder dust from waste material 12 obtained from the captured image, the more the operation of dust-proof section 60 is increased. In control device 50, it is possible to further suppress the operation shortage of dust-proof section 60 or the like according to the amount of waste materials 12, and it is possible to more appropriately execute the dust-proof processing. In addition, control section 51 executes the output processing of outputting the information regarding the maintenance with a tendency that the larger the amount of waste materials 12 obtained from the captured image and/or the amount of powder dust from waste material 12 obtained from the captured image, the shorter the output interval of the information regarding the maintenance of foreign substance removal device 30. In control device 50, it is possible to further suppress insufficient maintenance of dust-proof section 60 or the like according to the amount of waste materials 12, and it is possible to more appropriately execute maintenance of the device. In addition, in the output processing, control section 51 accumulates the operation amount of dust-proof section 60, and outputs the information regarding the maintenance when the accumulated operation amount reaches a predetermined maintenance execution amount. In control device 50, since the execution of the maintenance is notified according to the operation amount of dust-proof section 60, it is possible to more appropriately execute the maintenance of the device.

In addition, dust-proof section 60 includes one or more of gas circulation section 61 for circulating a gas for removing powder dust from waste material 12, liquid circulation section 65 for circulating a liquid for removing powder dust from waste material 12, and filter section 65 for filtering the powder dust from waste material 12. In control device 50, the circulation of gas or liquid, or filter 76 can remove powder dust. Furthermore, control device 50 can more appropriately control the operation thereof. Furthermore, removal section 34 removes foreign substance 14 present in waste material 12 based on the captured image captured by imaging section 32. In control device 50, the amount of waste materials 12 can be obtained using the foreign substance removal image captured by imaging section 32. Accordingly, it is possible to execute more appropriate maintenance of the device while further suppressing complications of the configuration without requiring other detection sections or the like.

In addition, foreign substance removal device 30 includes removal section 34 that picks up and removes foreign substance 14 from waste material 12 conveyed by conveyance device 22, dust-proof section 60 that performs dust-proofing related to the maintenance of foreign substance removal device 30 with respect to powder dust derived from waste material 12, imaging section 32 located upstream of removal section 34 and that captures the image of waste material 12, and the above-described control device 50. Since foreign substance removal device 30 includes control device 50 described above, it is possible to more appropriately execute maintenance of the device.

In addition, in dust-proof section 60, excessive operation can be further suppressed, and thus consumption of air, oil, and the like can be further suppressed. Furthermore, consumable items such as oil and a filter of dust-proof section 60 can be exchanged at an appropriate timing. Furthermore, in foreign substance removal device 30, since imaging section 32 that detects foreign substance 14 can be used, it is possible to obtain the information regarding the amount of waste materials 12 while further suppressing the addition of a configuration and further suppressing the additional cost.

It is needless to say that the present disclosure is not limited in any way to the above-described embodiments, and the present disclosure can be embodied in various aspects as long as the aspects fall within the technical scope of the present disclosure.

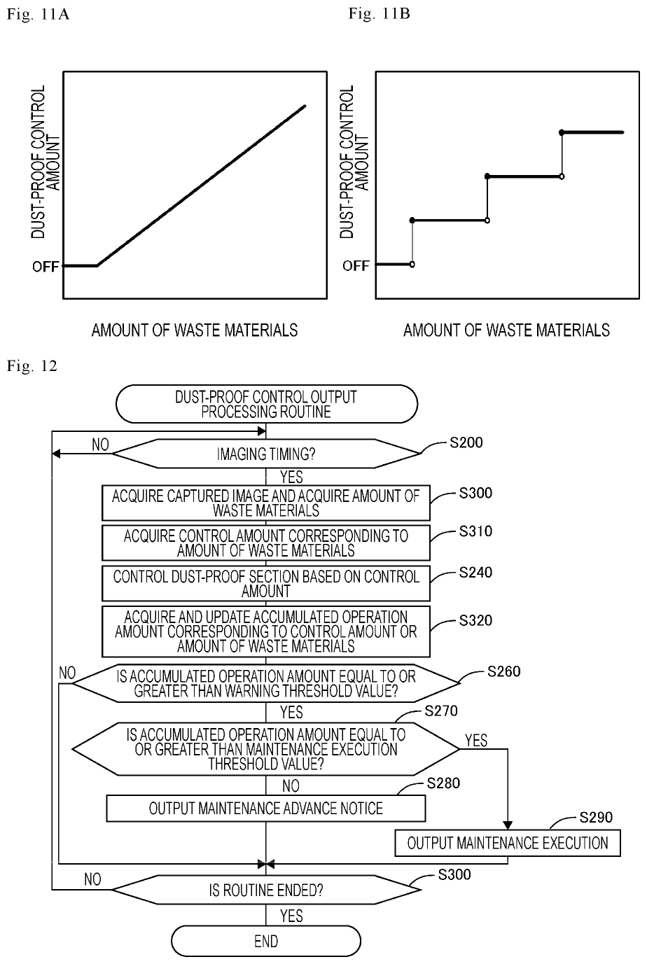

For example, in the embodiment described above, the amount of powder dust is acquired as the information regarding the amount of waste materials from the captured image, and the control processing and the output processing are executed based on the acquired amount of powder dust; however, the configuration is not particularly limited to this, and the output processing may be omitted. In addition, control device 50 uses the amount of powder dust; however, the configuration is not particularly limited to this, and may acquire the amount of waste materials and execute the control processing and the output processing based on the amount of waste materials. FIG. 10 is a diagram of correspondence relationship information including the correspondence relationship between the waste material image and the amount of waste materials. FIG. 11 is a diagram of correspondence relationship information including the correspondence relationship between the amount of waste materials and the dust-proof control amount. FIG. 12 is a flowchart illustrating an example of another dust-proof control output processing routine. In FIG. 12, the same steps as those in the dust-proof control output processing routine described above are denoted by the same reference numerals, and detailed descriptions thereof will be omitted. As illustrated in FIGS. 10 and 11, control device 50 may use the correspondence relationship in which the width or area of waste material 12 obtained from the captured image is associated with the amount of waste materials and the correspondence relationship information in which the amount of waste materials is associated with the control amount of dust-proof section 60. In addition, as illustrated in FIG. 12, control section 51 acquires the amount of waste materials in S300, acquires the control amount corresponding to the amount of waste materials in S310, and acquires the control amount or the accumulated operation amount according to the amount of waste materials in S320. Also in control device 50, since the information on the control and the maintenance of dust-proof section 60 is output according to the increase and decrease in the amount of waste materials, it is possible to execute more appropriate maintenance of the device.

In the above-described embodiment, although control section 51 obtains the amount of powder dust and the amount of waste materials from waste material 12 based on width W of waste material 12 included in the captured image, control section 51 may also obtain the amount of powder dust and the amount of waste materials from the area using width W. The area of waste material 12 may be acquired by multiplying width W of waste material 12 by a predetermined coefficient. In this case, the predetermined coefficient may be, for example, a predetermined distance (predetermined intervals) in conveyance direction D. Alternatively, multiple widths W may be acquired at multiple positions, and the area of waste material 12 may be acquired based on a line connecting acquired multiple widths W and a distance in conveyance direction D of a region including multiple positions. Alternatively, as the area of waste material 12, the area of waste material 12 in a predetermined region in the captured image may be acquired based on the captured image. In addition, in the above-described embodiment, the amount of powder dust or the amount of waste materials from waste material 12 is obtained based on width W of waste material 12; however, the configuration is not particularly limited to this. Control section 51 may acquire the height information of waste material 12 from detection section 33 located upstream of removal section 34 and that detects the height of the waste material, and obtain the amount of waste materials and/or the amount of powder dust from the waste material based on the height information of the waste material. For example, the amount of waste materials 12 can be obtained by deriving the volume of waste material 12 using width W, height H, and conveyance amount C of waste material 12. In control device 50, the information regarding the amount of waste materials can be obtained by relatively easy processing using the height of waste material 12. For example, detection section 33 may acquire a first distance from the detection section to the conveyance surface of conveyance device 22 and a second distance from the detection section to the upper portion of waste material 12. The difference between the first distance and the second distance may be acquired as the height of waste material 12.

In the embodiment described above, although dust-proof section 60 includes gas circulation section 61, liquid circulation section 65, and filter section 75, one or more of these components may be omitted, or other components may be added. In addition, gas circulation section 61 may be applied to other configurations such as each slider and control device 50, liquid circulation section 65 may be used for other configurations, and filter section 75 may be applied to other configurations.

In the above-described embodiment, in foreign substance removal device 30, imaging section 32 is used to detect a foreign substance present in the waste material and acquire the information regarding the amount of waste materials 12; however, the configuration is not particularly limited to this, and foreign substance removal device 30 may include multiple imaging sections. From the viewpoint of suppressing the complexity of the device, it is desirable not to include multiple imaging sections 32.

In the above-described embodiment, the present disclosure is described as foreign substance removal device 30 including control device 50; however, the configuration is not particularly limited to this, and the present disclosure may be applied to control device 50 itself, or may be applied to a control method.

Here, control device 50 of the present disclosure may be configured as follows. For example, a control device of the present disclosure is a control device used in a foreign substance removal device including a removal section configured to pick up and remove a foreign substance from a waste material conveyed by a conveyance device, a dust-proof section configured to perform dust-proofing related to maintenance of the foreign substance removal device with respect to powder dust derived from the waste material, and an imaging section located upstream of the removal section and configured to capture the image of the waste material, the control device including a control section configured to acquire an amount of powder dust as information regarding an amount of waste material from a captured image captured by the imaging section.

In this control device, the amount of powder dust is acquired as the information regarding the amount of waste material from the captured image obtained by capturing the image of the waste material. In this control device, since the amount of powder dust derived from the waste material can be obtained, it is possible to more appropriately execute the maintenance of the device when the foreign substance is removed from the waste material using the amount of powder dust.

A control method of the present disclosure is a control method used in a foreign substance removal device including a removal section configured to pick up and remove a foreign substance from a waste material conveyed by a conveyance device, a dust-proof section configured to perform dust-proofing related to maintenance of the foreign substance removal device with respect to powder dust derived from the waste material, and an imaging section located upstream of the removal section and configured to capture an image of the waste material, the control method including a step of executing one or more of control processing of controlling the dust-proof section based on information regarding an amount of waste material obtained from a captured image captured by the imaging section, and output processing of outputting information regarding the maintenance of the foreign substance removal device based on the information regarding the amount of waste material obtained from the captured image captured by the imaging section.

In this control method, similar to the control device described above, since the information on the control and the maintenance of the dust-proof section is output according to the increase and decrease in the amount of waste material, it is possible to more appropriately execute the maintenance of the device. In the control method, various aspects of the above-described control device may be adopted, or steps for achieving each function of the above-described control device may be added.

Alternatively, a control method of the present disclosure is a control method used in a foreign substance removal device including a removal section configured to pick up and remove a foreign substance from a waste material conveyed by a conveyance device, a dust-proof section configured to perform dust-proofing related to maintenance of the foreign substance removal device with respect to powder dust derived from the waste material, and an imaging section located upstream of the removal section and configured to capture the image of the waste material and removing the foreign substance contained in the waste material, the control method including a step of acquiring an amount of powder dust as information regarding an amount of waste material from a captured image captured by the imaging section.

In this control method, similar to the control device described above, since the amount of powder dust derived from the waste material can be obtained, it is possible to more appropriately execute the maintenance of the device using the amount of powder dust. In the control method, various aspects of the above-described control device may be adopted, or steps for achieving each function of the above-described control device may be added.

### INDUSTRIAL APPLICABILITY

The present disclosure can be used in technical fields such as recycling of industrial waste.

### REFERENCE SIGNS LIST

10: Recycling system,

12: Waste material,

13: Target object,

14: Foreign substance,

15: Primary crusher,

16: Primary magnetic separator,

17: Screen machine,

18: Secondary crusher,

19: Secondary magnetic separator,

20 to 25: Conveyance device,

30: Foreign substance removal device,

31: Recognition section,

32: Imaging section,

33: Detection section,

34: Removal section,

35: X-axis slider,

36: Drive mechanism,

37: Screw shaft,

38: Nut,

39: Motor,

40: Y-axis slider,

41: Lifting and lowering section,

42: Drive mechanism,

43: Screw shaft,

44: Nut,

45: Motor,

46: Pickup section,

48: Dust-proof cover,

50: Control device,

51: Control section,

52: Storage section,

53: Accumulated information,

54: Threshold value information,

55: Correspondence relationship information,

56: Cooling fan,

57: Support portion,

58: Removal head,

59: Dust box,

60: Dust-proof section,

61 Gas circulation section,

62: Air supply section,

63: Supply pipe,

64: Discharge port,

65: Liquid circulation section,

66: Slider dust-proof section,

67: Cleaning liquid tube,

68: Circulation pump,

70: Lifting and lowering dust-proof section,

71: Cleaning liquid tube,

72: Circulation pump,

75: Filter section,

76: Filter,

D: Conveyance direction,

M: Worker,

W, W1, W2: Width.

1. A control device used in a foreign substance removal device including a removal section configured to pick up and remove a foreign substance from a waste material conveyed by a conveyance device, a dust-proof section configured to perform dust-proofing related to maintenance of the foreign substance removal device with respect to powder dust derived from the waste material, and an imaging section located upstream of the removal section and configured to capture an image of the waste material, the control device comprising:
a control section configured to execute one or more of control processing of controlling the dust-proof section based on information regarding an amount of waste material obtained from a captured image captured by the imaging section, and output processing of outputting information regarding the maintenance of the foreign substance removal device based on the information regarding the amount of waste material obtained from the captured image captured by the imaging section.

2. The control device according to claim 1, wherein
the control section is configured to acquire an amount of powder dust as the information regarding the amount of waste material from the captured image, and execute the control processing and/or the output processing based on the acquired amount of powder dust.

3. A control device used in a foreign substance removal device including a removal section configured to pick up and remove a foreign substance from a waste material conveyed by a conveyance device, a dust-proof section configured to perform dust-proofing related to maintenance of the foreign substance removal device with respect to powder dust derived from the waste material, and an imaging section located upstream of the removal section and configured to capture an image of the waste material, the control device comprising:
a control section configured to acquire an amount of powder dust as information regarding an amount of waste material from a captured image captured by the imaging section.

4. The control device according to claim 3, wherein
the control section is configured to execute one or more of control processing of controlling the dust-proof section based on the amount of powder dust and output processing of outputting information regarding the maintenance of the foreign substance removal device based on the amount of powder dust.

5. The control device according to claim 1, wherein
the control section is configured to obtain the amount of waste material and/or an amount of powder dust from the waste material, based on information including at least a width of the waste material included in the captured image.

6. The control device according to claim 1, wherein
the control section is configured to acquire height information of the waste material from a detection section, and obtain an amount of waste material and/or the amount of powder dust from the waste material, based on the height information of the waste material, the detection section being located upstream of the removal section and configured to detect a height of the waste material.

7. The control device according to claim 1, wherein
the control section is configured to execute either control processing of controlling the dust-proof section with a tendency that the smaller the amount of waste material obtained from the captured image and/or an amount of powder dust from the waste material obtained from the captured image, the more an operation of the dust-proof section is suppressed, or output processing of outputting the information regarding the maintenance of the foreign substance removal device with a tendency that the smaller the amount of waste material obtained from the captured image and/or the amount of powder dust from the waste material obtained from the captured image, the longer an output interval of the information regarding the maintenance.

8. The control device according to claim 1, wherein
the control section is configured to execute either control processing of controlling the dust-proof section with a tendency that the larger the amount of waste material obtained from the captured image and/or an amount of powder dust from the waste material obtained from the captured image, the more an operation of the dust-proof section is increased, or output processing of outputting the information regarding the maintenance of the foreign substance removal device with a tendency that the larger the amount of waste material obtained from the captured image and/or the amount of powder dust from the waste material obtained from the captured image, the shorter an output interval of the information regarding the maintenance.

9. The control device according to claim 1, wherein
the control section is configured to execute the output processing of outputting the information regarding the maintenance of the foreign substance removal device based on the information regarding the amount of waste material obtained from the captured image captured by the imaging section, accumulate an operation amount of the dust-proof section in the output processing, and output the information regarding the maintenance when the accumulated operation amount reaches a predetermined maintenance execution amount.

10. The control device according to claim 1, wherein
the dust-proof section includes one or more of a gas circulation section configured to cause a gas to flow to remove powder dust from the waste material, a liquid circulation section configured to cause a liquid to flow to remove powder dust from the waste material, and a filter section configured to filter powder dust from the waste material.

11. The control device according to claim 1, wherein
the removal section is configured to remove a foreign substance present in the waste material based on the captured image captured by the imaging section.

12. A foreign substance removal device comprising:
a removal section configured to pick up and remove a foreign substance from a waste material conveyed by a conveyance device;
a dust-proof section configured to perform dust-proofing related to maintenance of the foreign substance removal device with respect to powder dust derived from the waste material;
an imaging section located upstream of the removal section and configured to capture an image of the waste material; and
the control device according to claim 1.

13. A control method used in a foreign substance removal device including a removal section configured to pick up and remove a foreign substance from a waste material conveyed by a conveyance device, a dust-proof section configured to perform dust-proofing related to maintenance of the foreign substance removal device with respect to powder dust derived from the waste material, and an imaging section located upstream of the removal section and configured to capture an image of the waste material, the control method comprising:
a step of executing one or more of control processing of controlling the dust-proof section based on information regarding an amount of waste material obtained from a captured image captured by the imaging section, and output processing of outputting information regarding the maintenance of the foreign substance removal device based on the information regarding the amount of waste material obtained from the captured image captured by the imaging section.

14. A control method used in a foreign substance removal device including a removal section configured to pick up and remove a foreign substance from a waste material conveyed by a conveyance device, a dust-proof section configured to perform dust-proofing related to maintenance of the foreign substance removal device with respect to powder dust derived from the waste material, and an imaging section located upstream of the removal section and configured to capture an image of the waste material, the control method comprising:
a step of acquiring an amount of powder dust as information regarding an amount of waste material from a captured image captured by the imaging section.
